(19) United States
(12) Patent Application Publication
(10) Pub. No.: US 2009/0001604 A1
(43) Pub. Date: Jan. 1, 2009

(54) Semiconductor Package and Method for Producing Same

(76) Inventors: Daisuke Tanaka, Tokyo (JP); Shintaro Yamamichi, Tokyo (JP); Hideya Murai, Tokyo (JP); Tadanori Shimoto, Tokyo (JP); Kaichirou Nakano, Tokyo (JP); Katsumi Maeda, Tokyo (JP); Katsumi Kikuchi, Tokyo (JP); Yoichiro Kurita, Kanagawa (JP); Kouji Soejima, Kanagawa (JP)

Correspondence Address: HAYES SOLOWAY P.C., 3450 E. SUNRISE DRIVE, SUITE 140, TUCSON, AZ, 85718, US

(21) Appl. No.: 11/817,669

(22) PCT Filed: Mar. 1, 2006
(86) PCT No.: PCT/JP2006/303882

§ 371 Date: Jan. 22, 2008

(30) Foreign Application Priority Data
Mar. 1, 2005 (JP) 2005-056233

(51) Int. Cl. H01L 23/485; H01L 21/56

(52) U.S. Cl. 257/778; 438/124; 257/E23.019; 257/E21.502

(57) ABSTRACT

An oxide layer and a metal layer composed of a gold- or platinum-group metal are formed in the stated order on a substrate. A wiring body having a wiring layer, insulating layer, via, and electrode is formed on the metal layer. A semiconductor element is then connected as a flip chip via solder balls on the wiring body electrode, and underfill is introduced between the semiconductor element and the wiring body. Subsequently, a sealing resin layer is formed so as to cover the semiconductor element and the surface of the wiring body on which the semiconductor element is mounted, thus producing a semiconductor package. A high-density, detailed, thin semiconductor package can thereby be realized.

### TECHNICAL FIELD

The present invention relates to a semiconductor package that carries one or a plurality of semiconductor elements on a wiring layer, and a method for producing same.

### BACKGROUND ART

In recent years, the number of terminals in semiconductor devices has increased along with increasing speeds and levels of integration, and the pitch of regions between terminals has also narrowed. For this reason, higher density and finer detail is desired in the wiring substrates on which these semiconductor elements are to be mounted. Recently, ceramic substrates, build-up substrates, tape substrates, and the like have commonly been used as mounting substrates.

Ceramic substrates are composed of an insulating substrate made from alumina or the like and a wiring conductor made from high-melting metal material such as tungsten (W) or molybdenum (Mo) formed on this insulating substrate (e.g., refer to patent document 1). In patent document 1, a semiconductor package is described employing a ceramic multilayer substrate produced by alternate layering of wiring layers and insulating layers composed of aluminum nitride.

Build-up substrates are produced by forming an insulating layer composed of resin on both surfaces of a printed substrate and then using an etching method and plating method to produce multiple layers by forming fine circuits of copper wiring on this insulating layer. The circuits on the front surface and circuits on the back surface are connected via through holes or the like (e.g., refer to patent documents 2 and 3). For example, patent document 2 describes a BGA (ball grid array) package in which semiconductor elements are carried on the surface of a build-up substrate, and molding resin seals the semiconductor elements and bonding wires that connect the semiconductor elements with the wiring formed on the surface of the substrate. With this BGA package, solder bumps are connected with the wiring formed on the back surface of the build-up substrate. In addition, patent document 3 describes a package for semiconductor devices that employs a build-up substrate in which an insulating layer composed of polyimide or the like is provided on one surface of a metal base composed of copper or aluminum in which a prescribed pattern is formed, with a wiring pattern formed on this insulating substrate. With this package for semiconductor devices, solder bumps are connected with the metal base pattern along with connection of semiconductor chips on the wiring pattern, and the semiconductor elements and wiring patterns are sealed with a cap formed from metal or resin.

In addition, tape substrates have wiring composed of copper or the like formed on an insulating film composed of polyimide or the like (e.g., refer to patent document 4). Patent document 4 describes a carrier tape in which a wiring pattern composed of copper is formed on one surface of a polyimide film, with a frame-form reinforcing part composed of copper formed on the other surface. In addition, via holes are provided to the inside of the frame-form reinforcing part from the side of the polyimide film.

Furthermore, in the past, semiconductor devices and methods for their production have been offered in which a thinner profile and improved semiconductor element dimensional stability prior to mounting have both been achieved by forming the wiring layer on a support substrates and then removing the support substrate after mounting the semiconductor elements (e.g., refer to patent documents 5 to 7). FIGS. 8A to 8C are sectional views showing the sequence of steps for the production method for semiconductor devices described in patent document 5. For example, when producing the semiconductor device 100 described in patent document 5, first, as shown in FIG. 8A, a wiring layer 102 is formed on a support substrate 101, and then semiconductor elements 103 and 104 are mounted on this wiring layer 102. Subsequently, as shown in FIG. 8B, the support substrate 101 is separated from the wiring layer 102, and, as shown in FIG. 8C, the wiring layer 102 with the mounted semiconductor elements 103 and 104 is mounted on the package substrate 106 via solder bumps 105. Patent document 5 describes a method in which separation of the wiring layer 102 and the support substrate 101 is facilitated by utilizing the poor adhesion of Cu with ceramics, wherein a ceramic plate such as aluminum nitride is used as the support substrate 101, a sputtered Cu film is formed on the ceramic plate, and a wiring layer 102 is then formed on this sputtered Cu film.

In addition, in the method for producing semiconductor devices described in patent document 6, a resin layer with poor adhesion with respect to silicon is formed on a support substrate composed of silicon, and a wiring layer is formed on this resin layer. In addition, FIGS. 9A and 9B are sectional views showing the sequence of steps of the method for producing the semiconductor device described in patent document 7. In the method for producing semiconductor devices described in patent document 7, the poor adhesion between metal or nitride layers and oxide layers is utilized. Specifically, as shown in FIG. 9A, a metal layer or nitride layer 112 is first formed on a support substrate 111, and then an oxide layer 113 and insulating layer 114 are sequentially formed on the metal layer or nitride layer 112. Next, a wiring layer 115 is formed on the insulating layer 114, and, as shown in FIG. 9B, the support substrate 111 and wiring layer 115 are separated at the interface between the metal or nitride layer 112 and the oxide layer 113.

[Patent document 1] Japanese Laid-Open Patent Application No. 8-330474

[Patent document 2] Japanese Laid-Open Patent Application No. 11-17058

[Patent document 3] Japanese Patent Publication No. 2679681

[Patent document 4] Japanese Laid-Open Patent Application No. 2000-58701

[Patent document 5] Japanese Laid-Open Patent Application No. 2003-142624

[Patent document 6] Japanese Laid-Open Patent Application No. 2000-347470

[Patent document 7] Japanese Laid-Open Patent Application No. 2003-174153

### DISCLOSURE OF THE INVENTION

### Problems to be Solved by the Invention

However, the above prior art has the following problems. Firstly, when a ceramic substrate such as the semiconductor package described in patent document 1 has been used, damage such as breakage or defects readily occurs in the substrate during production and transport because the ceramic is hard and brittle, and problems are accordingly presented in regard to loss of yield. In addition, when a ceramic substrate is used, the substrate is produced by printing wiring on a green sheet prior to firing, layering each of the sheets, and then firing. In this production process, however, shrinkage occurs as a result of high-temperature firing, causing warping of the fired substrate, which tends to produce shape defects such as deformation and dimensional variability. Due to the occurrence of these shape defects, the ceramic substrate is not sufficiently amenable to the extremely high levels of planarity required of substrates such as high density circuit substrates and flip chips. Specifically, due to shape defects, using ceramic substrates makes it more difficult to increase the density, the level of detail, and the pin numbers in the circuits. The planarity of the mounting regions for the semiconductor elements is also inferior. As a result, cracking, separation, and the like tend to occur in the regions of contact between the semiconductor elements and the substrate, and there are problems with loss of semiconductor element reliability.

In addition, when a build-up substrate is used, as with the semiconductor package described in patent documents 2 and 3, there are problems with the generation of substrate warping due to differences in thermal expansion between the printed substrate used as the core material and the resin insulating film formed on the surface thereof. As described above, substrate warping leads to damage during connection with semiconductor elements having large pin numbers and also reduces yield and impedes higher circuit density and detail.

When a tape substrate such as the carrier tape described in patent document 4 is used, shifting during mounting of the semiconductor elements increases as a result of shrinkage of the tape substrate, and a problem arises in that the substrate is not sufficiently amenable to increased circuit density.

When semiconductor package thickness is reduced by utilizing the poor adhesion between Cu and ceramics, as with the semiconductor device production method described in patent document 5, with certain ceramic materials the Cu disperses into the ceramic plate during production of the wiring regions, which increases binding in these regions and causes problems in regard to eventually achieving reliable separation. A further problem is presented in that the sputtered Cu layer is oxidized during processing, and separation occurs during wiring layer formation, making reliable production impossible.

As with the production method for semiconductor devices described in patent document 6, when a separation layer formed from a resin, specifically, the polyimide film exemplified in patent document 6, is used, swelling (floating) occurs between the resin layer and the silicon substrate during thermal treatment of the separating layer. A problem accordingly arises in that wiring layers cannot be produced thereupon.

When the thickness of a semiconductor package is reduced by utilizing the poor adhesion between oxide layers and metal layers or nitride layers, as with the production method for semiconductor devices described in patent document 7, the film formation temperature of the oxide layer is higher than the film formation temperature of the metal layer or nitride layer, leading to increased binding at the interface between the oxide layer and the metal layer or nitride layer, and causing problems with separation. The oxide layer remaining on the wiring layer side after separation is brittle; therefore, cracking loci tend to arise in subsequent steps, and a problem arises in that reliable production is not possible.

With the foregoing problems in view, it is an object of the invention to provide a semiconductor package and method for producing same, whereby higher densities, increased detail and reduced thickness can all be realized.

### Means for Solving the Problems

The semiconductor package pertaining to the first invention of this application has a substrate; an oxide layer formed on this substrate; a metal layer that is formed on this oxide layer and is composed of at least one metal selected from the group consisting of gold, platinum, palladium, rhodium, ruthenium, iridium and osmium; a wiring body formed on this metal layer and provided with at least one wiring layer; and one or a plurality of semiconductor elements mounted on this wiring body.

The wiring body is formed on the substrate in the present invention; therefore, the incidence of warping or other shape defects is low, and favorable planarity can be realized, making the invention well-suited for narrow pitches of about 20 to 50 μm in the gaps between the contact pads. As a result, an increase in the density and detail of the wiring body patterns can be realized while favorable connection reliability is preserved in the semiconductor device and semiconductor package yield is improved. In addition, with the semiconductor package, an oxide layer and a metal layer composed of a gold- or platinum-group metal are provided, so reliable separation can occur at the interface between the oxide layer and the metal layer, and the thickness can be dramatically reduced relative to semiconductor packages that employ conventional build-up substrates. In addition, the substrates that are used at this time can be reused, dramatically reducing production costs. Because the oxide layer and metal layer have appropriate binding strength, separation will not occur unless force is applied, allowing reliable performance of the wiring body formation step and semiconductor element mounting step.

The interface between the oxide layer and the metal layer preferably has lower binding strength relative to the other interfaces. Separation is thereby facilitated at the interface between the oxide layer and the metal layer.

The oxide layer can be formed from at least one oxide selected from the group consisting of TiO₂, Ta₂O₅, Al₂O₃, SiO₂, ZrO₂, HfO₂, Nb₂O₅, perovskite-type oxides, and Bi-based layered oxides. In this case, the perovskite oxide is, for example, at least one oxide selected from the group consisting of BaₓSr₁₋ₓTiO₃ (where 0≦x≦1), PbZrₓTi₁₋ₓO₃ (where 0≦x≦1), and Pb_{1-y}La_{y}ZrₓTi₁₋ₓO₃ (where 0≦x≦1 and 0<y<1). The Bi-based layered oxide is, for example, at least one oxide selected from the group consisting of BaₓSr₁₋ₓBi₂Ta₂O₉ (where 0≦x≦1) and BaₓSr₁₋ₓBi₄Ti₄O₁₅ (where 0≦x≦1).

In addition, the substrate can be formed from one material selected from the group consisting of semiconductor materials, metals, quartz, ceramics, and resins. In this case, examples of semiconductor materials include silicon, sapphire, and GaAs.

With these semiconductor packages, the wiring body may have insulating layers formed as top layers and/or bottom layers on the wiring layers. The wiring body also has electrodes that are electrically connected with the wiring layer formed on the surface on which the semiconductor element is mounted, and the semiconductor element may be electrically connected with the electrodes by means of one material selected from the group consisting of low-melting metals, conductive resins, and metal-containing resins. In this case, the semiconductor element can be connected as a flip chip.

In addition, there may also be a sealing resin layer that seals the semiconductor element and the surface of the wiring body on which the semiconductor element is mounted. In this case, the thickness of the sealing resin layer is preferably greater than the thickness of the semiconductor elements. In addition, the sealing resin layer, for example, can be formed from epoxy resin containing silica filler. Separation at the interface between the oxide layer and metal layer can accordingly be made to occur via the force generated when the resin cures during sealing resin layer formation.

The method for producing the semiconductor package according to the second invention of this application involves forming an oxide layer on the substrate, forming a metal layer composed of at least one metal selected from the group consisting of gold, platinum, palladium, rhodium, ruthenium, iridium, and osmium on the oxide layer, forming a wiring body having at least one layer of wiring layer on the metal layer, and mounting one or a plurality of semiconductor elements on the wiring body.

In the present invention, an oxide layer is formed on the substrate, and a metal layer formed thereupon is composed of at least one metal selected from the group consisting of gold, platinum, palladium, rhodium, ruthenium, iridium, and osmium. Consequently, a suitable force is applied, thereby bringing about separation. As a result, a high-density detailed wiring body can be reliably formed, and the substrate can be readily removed after the semiconductor element has been mounted.

This semiconductor package production method may also have a step involving separation at the interface between the oxide layer and the metal layer, thereby facilitating a reduction in thickness. In this case, patterning of the metal layer can be carried out after separation at the interface between the oxide layer and metal layer, thereby forming wiring or electrodes. Other semiconductor devices and semiconductor components can also be mounted, and increased functionality as a semiconductor device can be realized. Moreover, the wiring body is thin; therefore, the wiring distance between semiconductor devices mounted on both sides is shortened, allowing realization of high-speed signal transmission and increased bus width.

In the separation step referred to above, separation may be carried out by mounting the semiconductor elements and then forming a sealing resin layer so as to cover the semiconductor element and the surface of the wiring body on which the semiconductor element has been mounted. In this case, the thickness of the sealing resin layer can be greater than the thickness of the semiconductor elements, and the sealing resin layer can be formed from an epoxy resin containing silica filler.

The oxide layer can be formed from at least one oxide selected from the group consisting of TiO₂, Ta₂O₅, Al₂O₃, SiO₂, ZrO₂, HfO₂, Nb₂O₅, perovskite-type oxides, and Bi-based layered oxides. In this case, the perovskite oxide is, for example, at least one oxide selected from the group consisting of BaₓSr₁₋ₓTiO₃ (where 0≦x≦1), PbZrₓTi₁₋ₓO₃ (where 0≦x≦1), and Pb_{1-y}La_{y}ZrₓTi₁₋ₓO₃ (where 0≦x≦1 and 0<y<1). The Bi-based layered oxide is, for example, at least one oxide selected from the group consisting of BaₓSr₁₋ₓBi₂Ta₂O₉ (where 0≦x≦1) and BaₓSr₁₋ₓBi₄Ti₄O₁₅ (where 0≦x≦1).

In addition, the substrate can be formed using one material selected from the group consisting of a semiconductor material, metal, quartz, a ceramic, and a resin. In this case, the semiconductor material is, for example, one semiconductor material selected from the group consisting of silicon, sapphire, and GaAs.

Moreover, the semiconductor element and electrodes that are electrically connected with the wiring layer provided in the wiring body may be connected together using one material selected from the group consisting of a low-melting metal, a conductive resin, and a metal-containing resin. In this case, the semiconductor element can be connected as a flip chip.

### Effect of the Invention

According to the present invention, a wiring body is formed on a substrate, thereby allowing a wiring body provided with high density and high detail to be formed without any shape defects. Moreover, a laminated film formed from an oxide layer and a gold- or platinum-group metal can be provided between the substrate and wiring body. As a result, the substrate can be separated at the interface between the oxide layer and metal layer by applying a force after mounting the semiconductor elements on the wiring body, thus allowing the thickness to be easily reduced.

### BRIEF DESCRIPTION OF THE DRAWINGS

FIG. 1 is a sectional view showing the structure of the semiconductor package of Embodiment 1 of the present invention;

FIGS. 2A to 2D are sectional views showing the sequence of steps for the semiconductor package production method of Embodiment 1 of the present invention;

FIGS. 3A and 3B are sectional views showing the sequence of steps for the semiconductor package production method of Embodiment 1 of the present invention, where A shows the step subsequent to 2D;

FIG. 4 is a sectional view showing the structure of a semiconductor package of Embodiment 2 of the present invention;

FIGS. 5A and 5B are sectional views showing the sequence of steps for the semiconductor package production method of Embodiment 2 of the present invention;

FIG. 6 is a sectional view showing the structure of the semiconductor package of a first modified example of Embodiment 2 of the present invention.

FIG. 7 is a sectional view showing the structure of the semiconductor package of a second modified example of Embodiment 2 of the present invention.

FIGS. 8A to 8C are sectional views showing the sequence of steps for the semiconductor package production method described in patent document 5.

FIGS. 9A and 9B are sectional views showing the sequence of steps for the semiconductor package production method described in patent document 7.

### KEY

1: substrate

2, 113: oxide layer

3: metal layer

4a, 4b, 44, 102, 115: wiring layer

5a, 5b: insulating layer

6, 36: electrode

7: wiring body

8a, 8b: via

9: underfill

10: solder ball

11, 103, 104: semiconductor element

12: sealing resin

20, 30, 40, 50: semiconductor package

100: semiconductor device

101, 111: support substrate

105: solder bump

106: package substrate

112: metal layer or nitride layer

114: insulating layer

### BEST MODE FOR CARRYING OUT THE INVENTION

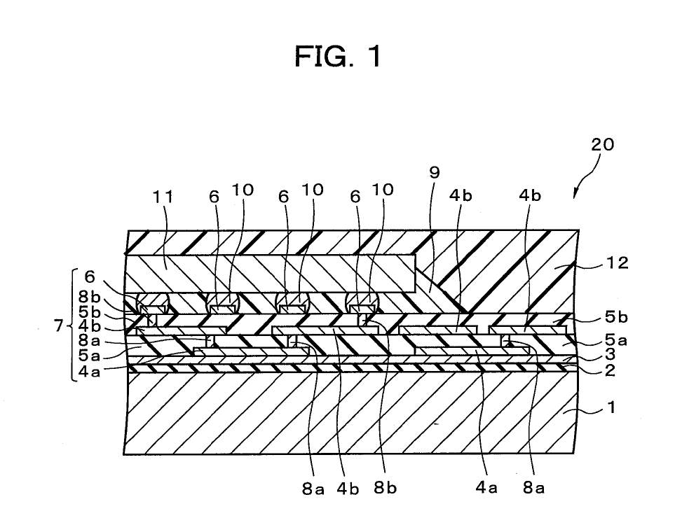

The semiconductor package according to the embodiments of the present invention is described in detail below in reference to the attached drawings. First, the semiconductor package of Embodiment 1 of the present invention will be discussed. FIG. 1 is a sectional view showing the structure of the semiconductor package of Embodiment 1. As shown in FIG. 1, the semiconductor package 20 of this embodiment has an oxide layer 2 formed on a substrate 1 and a metal layer 3 composed of a gold- or platinum-group metal formed on the oxide layer 2. A wiring body 7 having a wiring layer is formed on this metal layer 3, and a semiconductor element 11 is connected as a flip chip to this wiring body 7. In addition, underfill 9 is provided between the semiconductor element 11 and wiring body 7 in order to increase the strength of the connection region, and a sealing resin layer 12 is formed so as to cover the semiconductor element 11 and the surface of the wiring body 7 on which the semiconductor element 11 has been mounted.

The substrate 1 of the semiconductor package 20 of this embodiment preferably has suitable rigidity, and a substrate composed of a semiconductor wafer material such as silicon, sapphire, GaAs, or the like; a metal substrate; a quartz substrate; a glass substrate; a ceramic substrate; or a printed wiring board may be used. When the semiconductor elements are to be connected at a narrow pitch of 100 □m or less, it is preferable to use a substrate composed of a semiconductor wafer material such as silicon, sapphire, GaAs, or the like; and it is particularly preferable to use the silicon substrate that is used in the semiconductor element.

The oxide layer 2 is a layer for optimizing the binding force with the metal layer 3, while also preventing the substrate 1 and the metal layer 3 formed thereupon from reacting. The layer may be formed, for example, from at least one oxide selected from the group consisting of perovskite oxides such as BaₓSr₁₋ₓTiO₃ (BST; where 0≦x≦1), PbZrₓTi₁₋ₓO₃ (PZT; where 0≦x≦1), and Pb_{1-y}La_{y}ZrₓTi₁₋ₓO₃ (PLZT; where 0≦x≦1 and 0<y<1); Bi-based layered oxides such as BaₓSr₁₋ₓBi₂Ta₂O₉ (where 0≦x≦1) and BaₓSr₁₋ₓBi₄Ti₄O₁₅ (where 0≦x≦1); and TiO₂, Ta₂O₅, Al₂0₃, SiO₂, ZrO₂, HfO₂, and Nb₂O₅. Examples of formation methods that are suitable for use include sputtering methods, PLD (pulsed laser deposition) methods, MBE (molecular beam epitaxy) methods, ALD (atomic layer deposition) methods, MOD (metal organic deposition) methods, sol-gel methods, CVD (chemical vapor deposition) methods and anodizing methods.

The film thickness of the oxide layer 2 is preferably 10 to 600 nm, more preferably 50 to 300 nm. If the thickness of the oxide layer 2 is less than 10 nm, then it will not be possible to form a connected film on the substrate 1 due to roughness and steps present in the substrate 1. On the other hand, if the thickness of the oxide layer 2 exceeds 600 nm, then cracking will tend to occur due to internal stresses, and production costs will increase due to the extended film formation time.

The metal layer 3 can be formed from at least one metal selected from the group consisting of gold, platinum, palladium, rhodium, ruthenium, iridium, and osmium, thereby allowing optimization of the binding force between the oxide layer 2 and the metal layer 3. Specifically, the binding force at the interface of the oxide layer 2 and metal layer 3 is made lower than the binding forces at the other interfaces, and a value of 1.9 J/m² or greater is produced based on binding evaluation using the four-point bend test. By decreasing the binding strength at the interface between the oxide layer 2 and the metal layer 3 to below the binding forces of the other interfaces, the substrate 1 can be readily and reliably separated. In addition, by making the binding force at the interface between the oxide layer 2 and metal layer 3 at least 1.9 J/m², it is possible to prevent defects such as separation from occurring in subsequent steps. The method for evaluating binding carried out using the four-point bend test referred to above involves supporting the test piece between two rollers, and then measuring the maximum load until the point at which the test piece breaks while supplying the load using the two rollers from above the center of the test piece. From this maximum load, the externally released energy resulting from the occurrence of separation per unit surface area is determined as part of the elastic energy accumulated in the system due to flexural deformation. In this embodiment, the energy value determined by this method is used as the binding strength.

In addition, the metal layer 3 can be formed, for example, by using a sputtering method, colloidal method, CVD method, ALD method, or the like. The film thickness is preferably 10 to 400 nm, more preferably 100 to 200 nm. If the thickness of the metal layer 3 is less than 10 nm, then a connected film will not be formed on the oxide layer 2, whereas if the thickness of the metal layer 3 is greater than 400 nm, then production costs will increase due to an extended film formation time.

The oxide layer 2 and metal layer 3 need not be formed over just one surface of the substrate 1. For example, the oxide layer 2 and metal layer 3 may be formed over regions other than the periphery of the substrate 1, and the peripheral regions of the substrate 1 may be used for direct contact between the substrate 1 and insulating layer 5. The stability during package production can accordingly be increased.

The wiring body 7 is composed of wiring layers 4a and 4b, insulating layers 5a and 5b, vias 8a and 8b, electrodes 6, and the like. Specifically, the wiring layer 4a is formed on the metal layer 3, and the insulating layer 5a is formed so as to cover the metal layer 3 and wiring layer 4a. In addition, the wiring layer 4b is formed on the insulating layer 5a, and the wiring layer 4b is electrically connected with the wiring layer 4a by using the via 8a formed in the insulating layer 5a. In addition, the insulating layer 5b is formed so as to cover the insulating layer 5a and wiring layer 4b, and a plurality of electrodes 6 are formed on the insulating layer 5b. These electrodes 6 are electrically connected with the wiring layer 4b using the via 8b formed in the insulating layer 5b.

The wiring layers 4a and 4b in the semiconductor package 20 of this embodiment can be formed from at least one metal selected from the group consisting of copper, aluminum, nickel, gold, and silver, but copper is particularly preferred from the standpoint of electrical resistance and cost. When the wiring layers 4a and 4b are formed from nickel, reactions at the interface between the insulating layers 6a and 6b and other layers can be prevented, and it is possible to form an inductor or resistance wire having the characteristics of a magnetic material. In addition, the wiring 4a and 4b may be formed by means of a subtractive method, semi-additive method, or full-additive method. With subtractive methods, a resist of the prescribed pattern is formed on copper foil provided on a substrate composed of ceramic, resin, or the like. After etching the unwanted copper foil, the resist is removed to obtain the prescribed pattern. With semi-additive methods, electroless plating, sputtering or CVD is carried out in order to form a power supply layer, whereupon a resist that is open in the prescribed pattern is formed, and the electrolytic plating is deposited inside the open regions of the resist. After removing the resist, the power supply layer is then etched to obtain the prescribed wiring pattern. With full-additive methods, an electroless plating catalyst is adsorbed onto a substrate composed of ceramic, resin, or the like, whereupon a pattern is formed using a resist. Catalyst activation is then carried out with the resist remaining as an insulating film, and metal is deposited on the open regions of the resist film using an electroless plating method, thereby producing the prescribed wiring pattern.

In addition, insulating layers 5a and 5b are formed using photosensitive or non-photosensitive organic material such as polynorbornene, PBO (polybenzoxazole), BCB (benzocyclobutene), polyimide resin, phenol resin, polyester resin, urethane acrylate resin, epoxy acrylate resin, or epoxy. Of these photosensitive or non-photosensitive organic materials, polyimide resin and PBO can provide high reliability due to their superior mechanical characteristics such as film strength, tensile modulus, and break elongation.

The electrodes 6 can have a multilayered structure, for example. In this case, from the standpoint of solder ball wettability or ease of joining to the bonding wire, the top-most layer of the electrodes 6 is preferably formed from at least one metal selected from gold, silver, copper, aluminum, tin, and soldering material, or an alloy containing one or more of these metals.

The sealing resin layer 12 used in the semiconductor package 20 of this embodiment can be formed, for example, from epoxy resin containing silica filler. This sealing resin layer 12 is able to prevent water infiltrating the semiconductor element 11, while also protecting the semiconductor element from mechanical shock such as impact. After forming the sealing resin layer 12, it is preferable for the residual stress after sealing to be 0.3 to 34 MPa, specifically, 3 to 20 MPa.

Although corresponding wiring layers and insulating layers are provided to the wiring body 7 of the semiconductor package 20 in this embodiment, the present invention is not restricted to such cases. One or more individual wiring layer or insulating layer may also be provided. In addition, there are no particular restrictions on the sequence, and the insulating layer may be formed on the metal layer 3, whereupon the wiring layer may be formed thereupon.

With the semiconductor package 20 of this embodiment, the semiconductor 11 is connected as a flip chip using solder balls, but the present invention is not restricted to such a case. The semiconductor 11 may be attached to the wiring body 7 in a face-up condition, and may be connected to the wiring body 7 using wire bonding. In addition, when connecting as a flip chip, a method may be used involving bump connection or the like using low-melting metal or anisotropic conductive film rather than solder. In order to improve package rigidity, a stiffener composed of a metal frame or the like may be attached to the surface on which the semiconductor element 11 has been mounted.

Because the wiring body 7 is formed on the substrate 1 in the semiconductor package 20 of this embodiment, shape defects do not readily form, and detailed wiring layers 4a and 4b can be formed tightly, densely and at high density. In addition, a metal layer 3 composed of gold- or platinum-group metal and an oxide layer 2 are formed between the substrate 1 and the wiring body 7. Consequently, when a sealing resin layer 12, for example, is formed after mounting a semiconductor element on the wiring body 7, the substrate 1 can be separated off at the interface between the oxide layer 2 and the metal layer 3 using force, thereby allowing the thickness to be easily reduced.

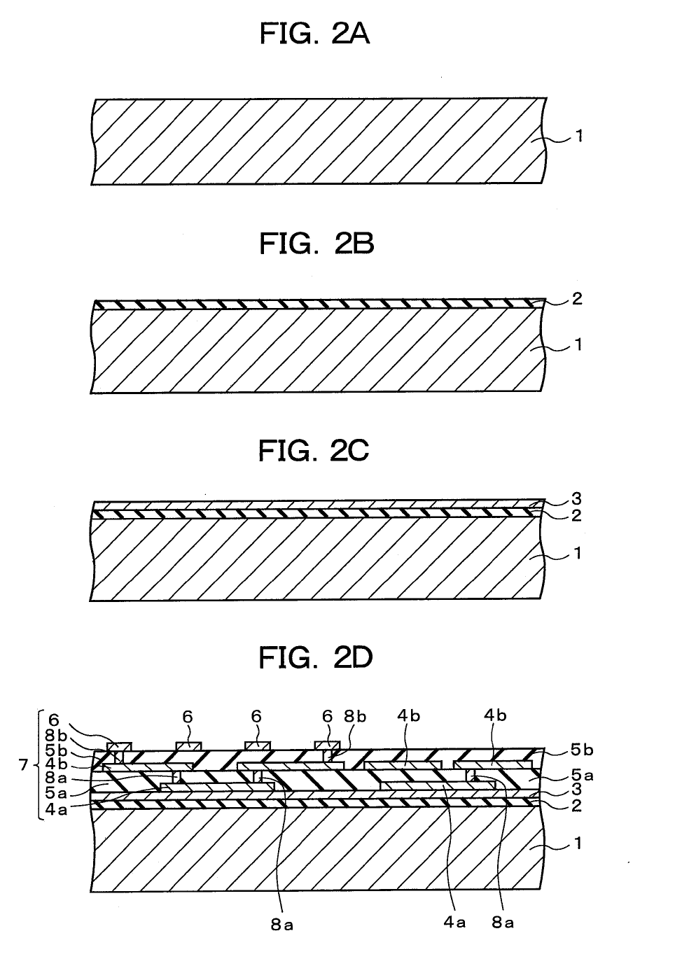

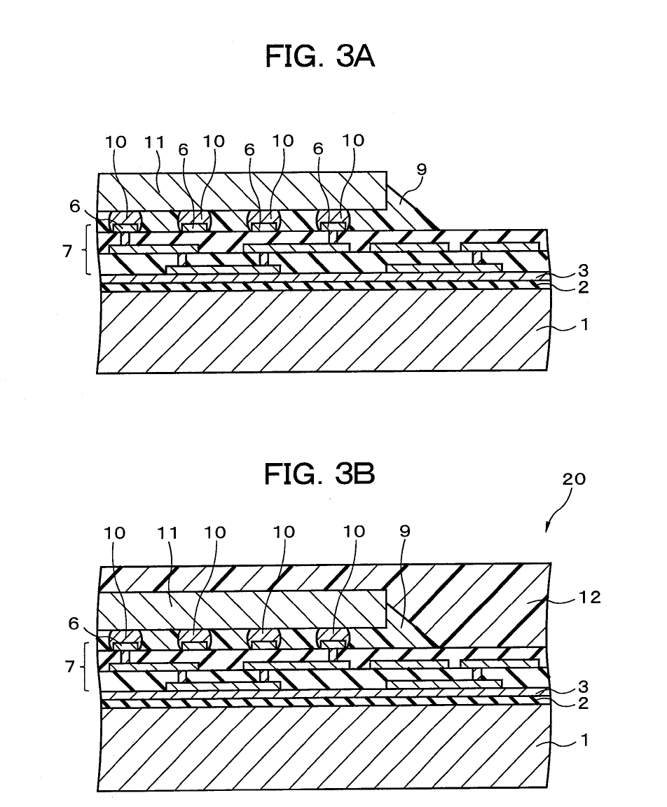

The method for producing the semiconductor package 20 of this embodiment is described below. FIGS. 2A to 2D and FIGS. 3A and 3B are sectional views showing the step sequence for the method for forming the semiconductor package of this embodiment. First, as shown in FIG. 2A, a silicon wafer with a diameter of, for example 20 mm (8 inches) and a thickness of, for example, 0.725 mm is prepared for use as the substrate 1. The substrate 1 is not restricted to a silicon wafer, and any substrate with a high degree of planarity and suitable rigidity may be used. Examples other than silicon substrates include substrates composed of semiconductor wafer material such as sapphire and GaAs, metal substrates, quartz substrates, glass substrates, ceramic substrates, and printed wiring boards. The size thereof may be selected appropriately.

As shown in FIG. 2B, a sputtering method, for example, may be used in order to form an oxide layer 2 with a thickness of, for example, 200 nm composed, for example, of SrTiO₃. When forming the oxide layer 2, a method other than a sputtering method may be used, such as a PLD method, MBE method, ALD method, MOD method, sol-gel method, CVD method, or anodizing method. In addition, the material from which the oxide layer 2 is formed is not restricted to SrTiO₃, and the layer may be formed from at least one oxide selected from the group consisting of perovskite oxides such as BaₓSr₁₋ₓTiO₃ (BST; where 0≦x≦1), PbZrₓTi₁₋ₓO₃ (PZT; where 0≦x≦1), and Pb_{1-y}La_{y}ZrₓTi₁₋ₓO₃ (PLZT; where 0≦x≦1 and 0<y<1); Bi-based layered oxides such as BaₓSr₁₋ₓBi₂Ta₂O₉ (where 0≦x≦1) and BaₓSr₁₋ₓBi₄Ti₄O₁₅ (where 0≦x≦1); and TiO₂, Ta₂O₅, Al₂O₃, SiO₂, ZrO₂, HfO₂, and Nb₂O₅. In addition, the film thickness of the oxide layer 2 can be 10 to 600 nm, preferably 50 to 300 nm.

As shown in FIG. 2C, a sputtering method can be used in order to form a metal layer 3 with a thickness of, for example, 150 nm composed of, for example, palladium on the oxide layer 2. The material for forming the metal layer 3 is not restricted to palladium, and may be at least one metal selected from gold, platinum, palladium, rhodium, ruthenium, iridium, and osmium. In addition to sputtering methods, a colloidal method, CVD method, ALD method, or the like may be used as this formation method. In addition, the film thickness of the metal layer 3 is preferably 10 to 400 nm, more preferably 100 to 200 nm.

Moreover, the binding strength at the interface between the oxide layer 2 and the metal layer 3 is lower than the binding strength at the other interfaces, and is preferably 1.9 J/m² or greater based on binding evaluation carried out using the four-point bend test method. As a result, the substrate can be readily and reliably separated, and separation can be prevented from occurring in subsequent steps, specifically, steps prior to the formation of the sealing resin layer 12.

As shown in FIG. 2D, the wiring body 7 is then formed on the metal layer 3. Specifically, using a method such as a subtractive method, semi-additive method, or full-additive method, a wiring layer 4a is formed that is composed, for example, of at least one metal selected from the group consisting of copper, aluminum, nickel, gold, and silver. When the wiring layer 4a is to be formed from copper using a subtractive method, copper foil is provided on the substrate 1 and a resist of the prescribed pattern is formed on this copper foil. After the unwanted copper foil is etched, the resist is removed to obtain the prescribed pattern. When the wiring layer 4a is to be formed using a semi-additive method, electroless plating, sputtering, or CVD is carried out in order to form a power supply layer, whereupon a resist that is open in the prescribed pattern is formed, and the electrolytic plating is deposited inside the open regions of the resist. After the resist is removed, the power supply layer is then etched to yield the prescribed wiring pattern. When the wiring layer 4a is to be formed using a full-additive method, electroless plating catalyst is adsorbed onto the substrate 1, whereupon a pattern is formed using a resist. Catalyst activation is then carried out with the resist remaining as an insulating film, and metal material for forming the metal 3 is deposited in the open regions of the resist film using an electroless plating method, thereby producing the prescribed wiring pattern.

Next, for example, an insulating layer 5a composed of a photosensitive or non-photosensitive organic material such as epoxy resin, epoxy acrylate resin, urethane acrylate resin polyester resin, phenol resin, polyimide resin, BCB, PBO, or polynorbornene resin is formed on the metal layer 3 so as to cover the wiring layer 4a, and a via 8a is then formed in this insulating layer 5a. When the insulating layer 5a is formed from photosensitive organic material, the opening region for forming the via 8a can be formed by photolithography. In addition, when the insulating layer 5a is formed from a non-photosensitive organic material or a photosensitive organic material having low pattern resolution, the opening for forming the via 8a can be formed using a laser processing method, dry etching method, or blast method. In addition, the via 8a can be formed by forming a plating post in advance in the position of the via 8a, then forming a resist layer 5a, and cutting away the insulating layer 5a by polishing to expose the plating post. With this method, it is not necessary to provide an opening region in advance in the insulating layer 5a.

Next, by a method similar to the method used for the wiring layer 4a described above, a wiring layer 4b that connects with the wiring layer 4b through the via 13a and is composed of at least one metal selected from the group consisting of, for example, copper, aluminum, nickel, gold, and silver is formed on the insulating layer 5a. In addition, by a method similar to the method used for the wiring layer 5a described above, an insulating layer 5b is formed that is composed of a photosensitive or non-photosensitive material such as epoxy resin, epoxy acrylate resin, urethane acrylate resin, polyester resin, phenol resin, polyimide resin, BCB, PBO, polynorbornene resin, or the like so as to cover this wiring layer 4b. A via 8b is then formed on the insulating layer 5b by a method similar to the method used for the via 8a described above.

Next, for example, a copper thin film having a thickness of 2 μm, a nickel thin film having a thickness of 3 μm, and a gold thin film having a thickness of 1 μm are layered in sequence on the insulating layer 5b, and electrodes 6 are formed that are electrically connected with the wiring layer 4b through the via 8b. In the method for forming the semiconductor package in this embodiment, the top-most layer of the electrodes 6 is formed from gold, but the present invention is not restricted to such a case. The top-most layer of the electrodes 6 can be formed from at least one metal selected from the group consisting of gold, silver, copper, aluminum, tin, and solder material, or an alloy containing at least one of these metals. The wettability of the solder balls formed on the electrodes 6 or the connections thereof with the bonding wire is accordingly improved.

Next, as shown in FIG. 3A, the electrodes of the semiconductor element 11 (not shown) are electrically connected with the electrodes 6 using solder balls 10, thereby mounting the semiconductor device 11 on the wiring body 7. Subsequently, in order to improve the strength of the joint regions, underfill 9 is introduced between the semiconductor element 11 and wiring body 7. In the production method for the semiconductor package of this embodiment, the semiconductor element 11 is connected as a flip chip by the solder balls 10, but the present invention is not restricted to such a case. After the semiconductor element 11 is attached to the wiring body 7 in a face-up condition, connections may be produced by means of wire bonding. In addition, even with flip chip connections, a connection method that does not employ solder material may be used, such as anisotropic conductive film, low-melting bump connection, or the like. In addition, in order to improve the rigidity of the package, a stiffener composed of a metal frame may be attached to the surface on which the semiconductor element 11 is mounted.

Next, as shown in FIG. 3B, the semiconductor element 11 is molded using a sealing resin 12 composed of epoxy resin containing, for example, silica filler. A material that produces a cured residual stress of 0.3 to 34 MPa, preferably 3 to 20 MPa, is preferably used for the sealing resin.

In the production method for the semiconductor package of this embodiment, the wiring layer 4a is provided to the metal layer 3, but the present invention is not restricted to such a case. An insulating layer may be formed on the metal layer 3, and the wiring layer may be formed thereupon. In addition, the oxide layer 2 and metal layer 3 need not be formed so as to cover one surface of the substrate 1. For example, the oxide layer 2 and metal layer 3 may be formed over regions other than the peripheral region of the substrate 1, and the peripheral region of the substrate 1 may be formed so that the substrate 1 and insulating layer 5 are in direct contact. The stability during package production can accordingly be improved.

In the method for producing the semiconductor package 20 of this embodiment, the wiring body 7 is formed on the substrate 1, and thus shape defects were inhibited, allowing detailed wiring layers 4a and 4b to be formed at high density. In addition, the oxide layer 2 and the metal layer 3 composed of gold- or platinum-group metal are formed in sequence on the substrate 1; therefore, the binding strength between these layers is not excessive, and the interface between the oxide layer 2 and the metal layer 3 can have a lower degree of binding than the other layers, with a value of 1.9 J/m² or greater based on binding evaluation carried out using the four-point bend test method. As a result, the semiconductor element will not separate before being mounted on the wiring body 7. For example, forming the sealing resin layer 12 and applying force enables separation to occur at the interface between the oxide layer 2 and the metal layer 3.

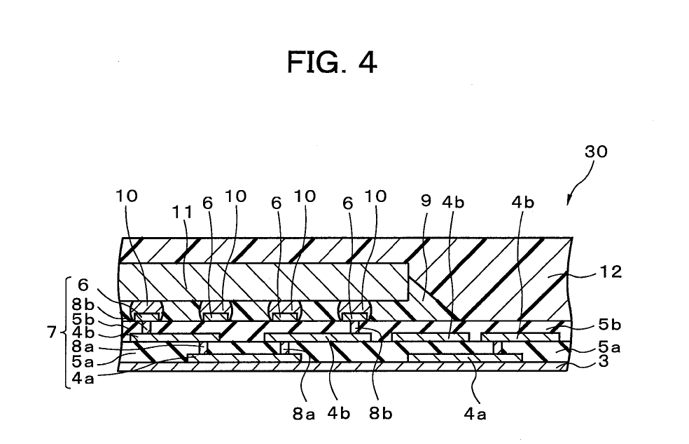

The semiconductor package of Embodiment 2 of the present invention is described below. FIG. 4 is a sectional view showing the structure of the semiconductor package of this embodiment. In FIG. 4, the same symbols are assigned to the same constituent elements as in the semiconductor package shown in FIG. 1, and detailed descriptions are not given. As shown in FIG. 4, the semiconductor package 30 of this embodiment has the substrate 1 and oxide film 2 removed from the semiconductor package of Embodiment 1 shown in FIG. 1. Specifically, the wiring layers 4a and 4b, the insulating layers 5a and 5b, the vias 8a and 18b, and the wiring body 7 having electrodes 6 are formed on the metal layer 3. In addition, the semiconductor element 11 is connected as a flip chip on the wiring body 7. Specifically, the electrodes 6 of the wiring body 7 and the electrodes of the semiconductor 11 (not shown) are connected via solder balls 10. In order to improve the strength of the connection regions, underfill 9 is introduced between the semiconductor element 11 and the wiring body 7. In addition, sealing resin layer 12 is formed so as to cover the semiconductor element 11 and the surface on which the semiconductor 11 is mounted on the wiring body 7.

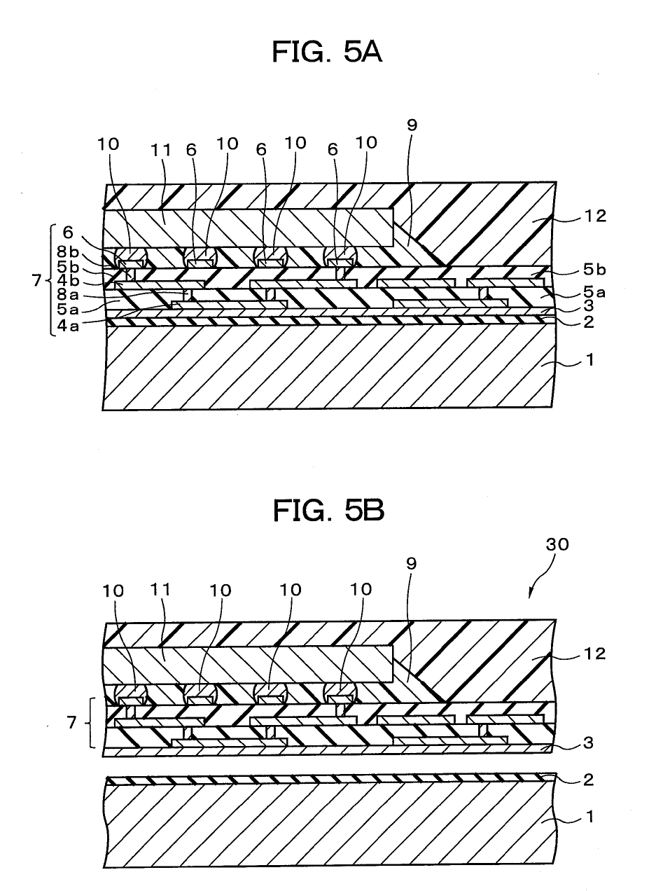

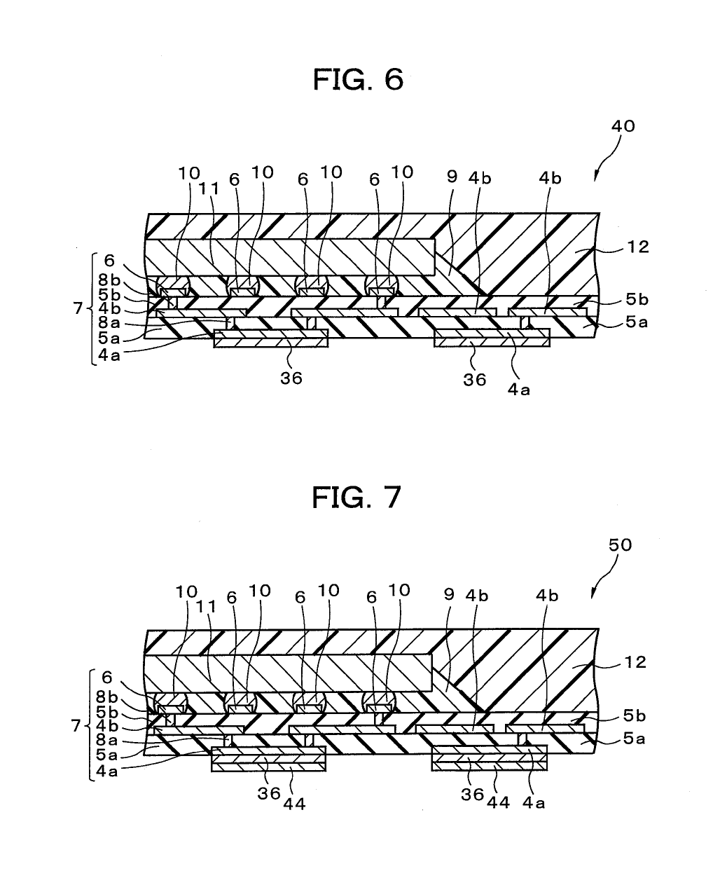

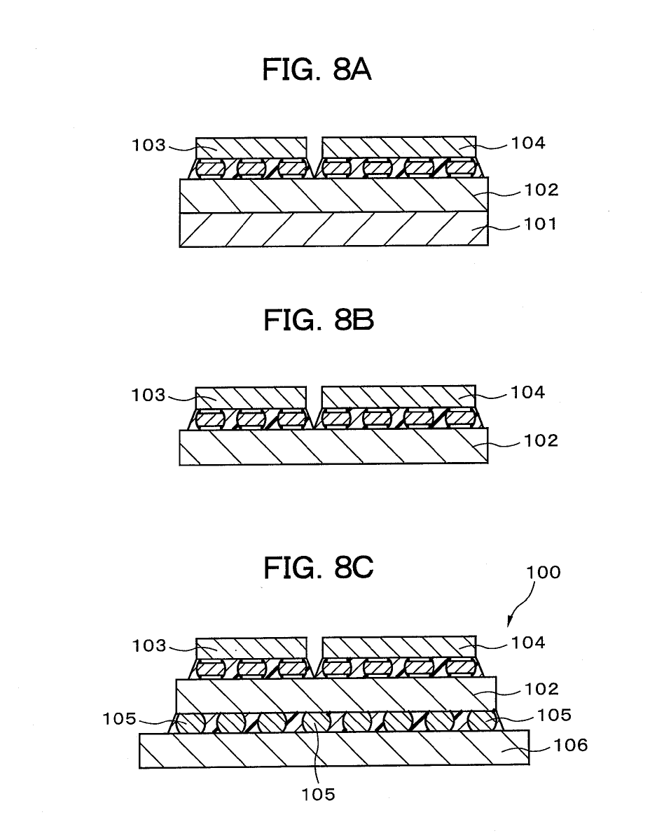

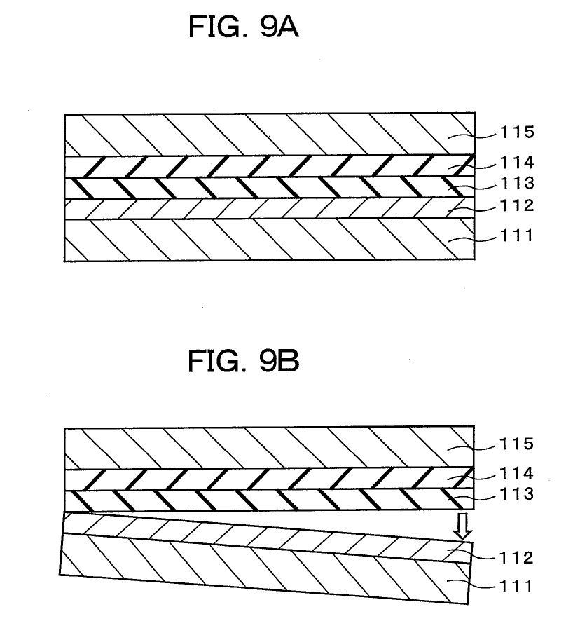

The method for producing the semiconductor package 30 of this embodiment is described below. FIGS. 5A and 5B are sectional views showing the sequence of steps for the production method for the semiconductor package of this embodiment. First, a semiconductor package having the structure shown in FIG. 6A is prepared by the methods shown in FIGS. 2A to 2D and FIGS. 3A and 3B. Next, as shown in FIG. 6B, the substrate 1 is separated at the interface between the oxide layer 2 and the metal layer 3. In the production of the semiconductor package 30 of this embodiment, the binding strength at the interface between the oxide layer 2 and the metal layer 3 is less than the binding strength of the other interfaces, and thus the force generated due to contraction upon curing the sealing resin layer 12 brings about reliable spontaneous separation in this region.

In the production method for the semiconductor package of this embodiment, the stress generated as a result of molding the semiconductor element 11 using the sealing resin layer 12 is utilized for separation, but the present invention is not restricted to such a case. At the stage where the semiconductor element 11 has been formed, an external stress that is equivalent to the stress generated by contraction upon curing of the sealing resin layer 12 can be applied physically, thereby separating the oxide layer 2 and the metal layer 3. The method whereby a stress equivalent to the stress in the sealing resin layer is applied in this manner, for example, is a method in which a removable thick film resist is formed on the surface of the wiring body 7 on which the semiconductor element 11 has been mounted. A semiconductor package that does not have a sealing resin layer can accordingly be produced using a stiffener or heat spreader, as with FCBGA (flip chip ball grid array) packages and the like for semiconductors having in excess of 1000 connection pads.

In addition, at the stage where the wiring body 7 is formed, an external stress that is equivalent to the stress generated by shrinkage upon curing of the sealing rosin layer 12 may be physically applied to separate the oxide layer 2 and the metal layer 3. A thin substrate that is able to be employed in various applications can accordingly be produced. Moreover, after the substrate 1 has been separated, the form may be processed to the desired size, and, in cases where a plurality of semiconductor elements is mounted, separation between the elements can be carried out by dicing or the like.

A semiconductor package according to a first modified example of Embodiment 2 of the present invention is described below. FIG. 6 is a sectional view showing the structure of the semiconductor package of the modified example. In FIG. 6, the same symbols are assigned to the same constituent elements as in the semiconductor package shown in FIG. 4, and further descriptions are not given. As shown in FIG. 6, the semiconductor package 40 of this modification is produced by processing the metal layer 3 of the semiconductor package of Embodiment 2 to produce back surface electrodes 36. Additional semiconductor elements and/or passive elements may be connected to these back surface electrodes 36.

The method for forming the back surface electrodes 36 by processing the metal layer 3, for example, is a method wherein a resist that has been patterned into the desired form is used as a mask, and unwanted regions are removed by dry etching or wet etching. In addition, a wiring layer may be formed rather than the back surface electrodes 36. The metal layer 3 is a thin film, and the resist film used for etching can be made thin, thereby allowing detailed pattern formation of the type used for forming semiconductor wiring and also allowing an increase in the wiring utilization ratio. Moreover, because the metal layer 3 is formed from a gold- or platinum-group metal, oxidation does not readily occur and reliable metal bonding can be produced. In addition, because dense films can be formed by the film formation method, connections can be made using wire bonding, solder, or the like without performing a pretreatment.

Semiconductor elements can be mounted on both surfaces of the wiring body 7 in the semiconductor package of this modified example, thereby realizing higher functionality as a semiconductor device. In addition, because the wiring body 7 is thin, the wiring distance between semiconductor devices mounted on the two surfaces is short, and high-speed signal transmission and a broad bus width can be realized. Other configurations and effects of the semiconductor package of this modified example are similar to the semiconductor package of Embodiment 2 described above.

The semiconductor package according to a second modified example of Embodiment 2 of the present invention is described below. FIG. 7 is a sectional view showing the structure of the semiconductor package of this modified example. In FIG. 7, the same symbols are assigned to the same constituent elements as in the semiconductor package shown in FIG. 4, and further descriptions are not given. As shown in FIG. 7, the semiconductor package 50 of this modified example has a wiring layer 44 composed of at least one metal selected from the group consisting of, for example, copper, aluminum, nickel, gold, and silver formed on the back surface electrodes 36 of the semiconductor package 40 of the above first modified example. The wiring layer 44 preferably is formed from copper from the standpoint of electrical resistance and cost. In addition, by increasing the thickness of the wiring layer 44, it is possible to improve electrical characteristics, and thus the thickness of the wiring layer 44 is preferably 5 to 15 □m. The wiring layer 44 can be formed, for example, by a semi-additive method in which the back surface electrode 36 is used as the power supply layer. Semiconductor elements and/or passive elements and the like may be mounted on the wiring layer 44.

Increased functionality as a semiconductor device can be realized in the semiconductor package 50 of this modified example. In addition, because the wiring body 7 is thin, the wiring distance between semiconductor devices mounted on the two surfaces is short, and high-speed signal transmission and a broad bus width can be realized. Other configurations and effects of the semiconductor package of this modified example are similar to the semiconductor package of Embodiment 2 described above.

### INDUSTRIAL APPLICABILITY

The present invention is effective for increasing density, detail, and thinness in semiconductor packages.

1. A semiconductor package, comprising:
a substrate;
an oxide layer formed on said substrate;
a metal layer that is formed on said oxide layer and is composed of at least one metal selected from the group consisting of gold, platinum, palladium, rhodium, ruthenium, iridium, and osmium;
a wiring body formed on said metal layer and provided with at least one wiring layer; and
one or a plurality of semiconductor elements mounted on said wiring body.

2. The semiconductor package according to claim 1, wherein the binding strength at an interface between said oxide layer and said metal layer is lower than at other interfaces.

3. The semiconductor package according to claim 1, wherein said oxide layer is formed from at least one oxide selected from the group consisting of TiO₂, Ta₂O₅, Al₂O₃, SiO₂, ZrO₂, HfO₂, Nb₂O₅, a perovskite-type oxide, and a Bi-based layered oxide.

4. The semiconductor package according to claim 3, wherein said perovskite oxide is at least one oxide selected from the group consisting of BaₓSr₁₋ₓTiO₃ (where 0≦x≦1), PbZrₓTi₁₋ₓO₃ (where 0≦x≦1), and Pb_{1-y}La_{y}ZrₓTi₁₋ₓO₃ (where 0≦x≦1 and 0<y<1).

5. The semiconductor package according to claim 3, wherein said Bi-based layered oxide is at least one oxide selected from the group consisting of BaₓSr₁₋ₓBi₂Ta₂O₉ (where 0≦x≦1) and BaₓSr₁₋ₓBi₄Ti₄O₁₅ (where 0≦x≦1).

6. The semiconductor package according to claim 1, wherein said substrate comprises one material selected from the group consisting of a semiconductor material, a metal, quartz, a ceramic, and a resin.

7. The semiconductor package according to claim 6, wherein said semiconductor material is one semiconductor material selected from the group consisting of silicon, sapphire, and GaAs.

8. The semiconductor package according to claim 1, wherein said wiring body has an insulating layer formed on the top layer and/or bottom layer of said wiring layer.

9. The semiconductor package according to claim 1, wherein
said wiring body has an electrode that is formed on the surface on which said semiconductor element is mounted and that is electrically connected with said wiring layer; and
said semiconductor device is electrically connected with said electrode using one material selected from the group consisting of a low-melting metal, a conductive resin, and a metal-containing resin.

10. The semiconductor package according to claim 9, wherein said semiconductor element is connected as a flip chip.

11. The semiconductor package according to claim 1, characterized in having a sealing resin layer for sealing said semiconductor element and the surface of said wiring body on which said semiconductor element is mounted.

12. The semiconductor package according to claim 11, wherein the thickness of said sealing resin layer is greater than the thickness of said semiconductor element.

13. The semiconductor package according to claim 11, wherein said sealing resin layer is formed from an epoxy resin containing silica filler.

14. A method for producing a semiconductor package, comprising the steps of:
forming an oxide layer on a substrate;
forming a metal layer having at least one metal selected from the group consisting of gold, platinum, palladium, rhodium, ruthenium, iridium, and osmium on said oxide layer;
forming a wiring body having at least one wiring layer on said metal layer; and
mounting one or a plurality of semiconductor elements on said wiring body.

15. The method for producing a semiconductor package according to claim 14, further comprising the step of separating at the interface between said oxide layer and said metal layer.

16. The method for producing a semiconductor package according to claim 15, wherein after said semiconductor element has been mounted, separation is caused by forming a sealing resin layer so as to cover said semiconductor element and the surface of said wiring body on which said semiconductor element is mounted.

17. The method for producing a semiconductor package according to claim 16, wherein the thickness of said sealing resin layer is made thicker than the thickness of said semiconductor element.

18. The method for producing a semiconductor package according to claim 16, wherein said sealing resin layer is formed using an epoxy resin having silica filler.

19. The method for producing a semiconductor package according to claim 15, wherein separation is performed at the interface of said oxide layer and said metal layer, whereupon said metal layer is pattered to form wiring or an electrode.

20. The method for producing a semiconductor package according to claim 14, wherein said oxide layer is formed from at least one oxide selected from the group consisting of TiO₂, Ta₂O₅, Al₂O₃, SiO₂, ZrO₂, HfO₂, Nb₂O₅, a perovskite-type oxide, and a Bi-based layered oxide.

21. The method for producing a semiconductor package according to claim 20, wherein said perovskite oxide is at least one oxide selected from the group consisting of BaₓSr₁₋ₓTiO₃ (where 0≦x≦1), PbZrₓTi₁₋ₓO₃ (where 0≦x≦1), and Pb_{1-y}La_{y}ZrₓTi₁₋ₓO₃ (where 0≦x≦1 and 0<y<1).

22. The method for producing a semiconductor package according to claim 20, wherein the Bi-based layered oxide is at least one oxide selected from the group consisting of BaₓSr₁₋ₓBi₂Ta₂O₉ (where 0≦x≦1) and BaₓSr₁₋ₓBi₄Ti₄O₁₅ (where 0≦x≦1).

23. The method for producing a semiconductor package according to claim 14, wherein said substrate is one material selected from the group consisting of a semiconductor material, a metal, quartz, a ceramic, and a resin.

24. The method for producing a semiconductor package according to claim 23, wherein said semiconductor material is one semiconductor material selected from the group consisting of silicon, sapphire, and GaAs.

25. The method for producing a semiconductor package according to claim 14, wherein said semiconductor element and an electrode that is provided to said wiring body and electrically connected with said wiring layer are connected together by one material selected from the group consisting of a low-melting metal, a conductive resin, and a metal-containing resin.

26. The method for producing a semiconductor package according to claim 25, wherein said semiconductor element is connected as a flip chip.
